(19) United States
(12) Patent Application Publication
(10) Pub. No.: US 2008/0093693 A1
(43) Pub. Date: Apr. 24, 2008

(54) Nanowire sensor with variant selectively interactive segments

(76) Inventors: Theodore I. Kamins, Palo Alto, CA (US); Shashank Sharma, San Jose, CA (US); Philip J. Kuekes, Menlo Park, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/584,148

(22) Filed: Oct. 20, 2006

(51) Int. Cl. H01L 29/84

(52) U.S. Cl. 257/419

(57) ABSTRACT

A nanowire sensor is operable to detect one or more species. The nanowire sensor includes a nanowire having a plurality of variant selectively interactive segments. Each of the variant selectively interactive segments are configured to simultaneously interact with the species to modulate the conductance of the nanowire for detecting the species.

### BACKGROUND

In recent years, nanowires have gained importance as sensors for detecting species in fluid analytes. Conventional nanowire sensors consist of a single undifferentiated segment, which interacts with a species in an analyte. A detection of the interaction between the nanowire and the species provides an indication that the species is present in the analyte. However, the single undifferentiated segment of conventional nanowire sensors may interact with many different species. This is due to the fact that many different species have similar properties, and therefore, many different species may interact in a similar manner with the single undifferentiated nanowire.

Therefore, the use of conventional nanowire sensors often results in false positive readings, because a nanowire having only a single undifferentiated segment may have a similar interaction with many different species. Thus, an accurate identification of a particular species is difficult to obtain with conventional nanowire sensors. In order to increase the accuracy of a conventional nanowire sensor, the analyte must be retested multiple times with different nanowire sensors.

However, multiple redundant testing on the same analyte is time consuming and wasteful. It is often undesirable or impossible to retest an analyte multiple times due to the small and limited nature of the species in the analyte. Each time a species is handled a certain percentage of the species is inevitably lost through unavoidable laboratory realities, such as adherence of the species to containers and equipment, evaporation, etc. Therefore, it is desirable to test the species as few times as possible.

Moreover, testing a species multiple times with different nanowire sensors often exacerbates the problem of obtaining false positive readings. This is because it is difficult to verify that the same species is interacting with each of the different nanowire sensors, for example, due to contamination of the analyte caused by performing multiple tests.

In addition, the use of multiple nanowire sensors increases the physical size of the sensor. This is due to the fact that, while a nanowire itself is relatively small, the electrodes to which the nanowire is attached and the external circuitry required to measure the interaction of the nanowire with a species is relatively large. Accordingly, the use of multiple nanowire sensors dramatically increases the overall physical size of the sensor.

### BRIEF DESCRIPTION OF THE DRAWINGS

Various features of the embodiments can be more fully appreciated, as the same become better understood with reference to the following detailed description of the embodiments when considered in connection with the accompanying Figures.

FIGS. 1A-B illustrate nanowires having variant selectively interactive segments, according to an embodiment;

FIGS. 2A-C illustrate a nanowire sensor interacting with different species, according to an embodiment;

FIG. 3A illustrates a nanowire sensor including multiple nanowires, according to an embodiment;

FIG. 3B illustrates logic functions performed by the nanowire sensor shown in FIG. 3A, according to an embodiment; and

FIG. 4 illustrates a flow chart of a method for detecting at least one species, according to an embodiment.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures have not been described in detail so as not to unnecessarily obscure the embodiments.

According to an embodiment, a nanowire sensor is operable to detect multiple properties of a species. A nanowire in the sensor contains a plurality of selectively interactive segments. Selectively interactive segments, which will be described in greater detail below, are delineated segments of the nanowire, which are configured to interact with a particular species or class of species. A species refers to any organic or inorganic material, including any, atom, molecule, ion, element, compound, DNA strand, virus, bacterium, etc., or any moiety thereof. As used herein, the term species may also include a class of species. A class of species refers to any conglomerate of different species that have a common characteristic. A common characteristic may be a molecule that is common to all the species in the class. A group of carcinogenic molecules may be in one class of species. The selectively interactive segments may also be configured to detect different species that are not in the same class. For example, a substance is known to include two different species. A nanowire may include selectively interactive segments configured to detect the two species, which is indicative of the substance being detected.

Interact, as used herein, refers to any association between a selectively interactive segment of a nanowire and a species that results in a modulation in the conductance of the selectively interactive segment. Conductance refers to the ability of an electric current to flow along a path, which is the reciprocal of resistance, and modulation in conductance refers to any change in conductance. For example, modulation in conductance may refer to a transition of conductance between two states. That is, a selectively interactive segment may transition from a non-conducting state to a conducting state, or vice versa. A non-conducting state generally means that no current is flowing through the nanowire, however, a non-conducting state may include a minor amount of current flow, which is negligible or a substantially different amount when compared to the current flow when the selectively interactive segment is in the conducting state. For example, a few picoamps may be flowing in a nanowire in a non-conducting state and 20 or more microamps may be flowing in a nanowire in a conducting state. However, the amount of current flowing in each state is largely dependent on the configuration of the nanowire, such as the length, diameter, thickness, width, materials used to compose the nanowire, etc. An entire nanowire may be in a conducting state or a non-conducting state depending on whether one or more species interacts with the selectively interactive segments of the nanowire, as described in further detail below.

In one embodiment, the modulation in conductance of a selectively interactive segment may be attributed to a charge carried by a species. Therefore, when the species associates with the selectively interactive segment, the charge carried by the species induces a current in the selectively interactive segment. In another embodiment, the species may alter some aspect of the selectively interactive segment, such as the shape of a layer of the selectively interactive segment, to allow the charge in the layer of the selectively interactive segment to move closer to the surface of the inner portion of the selectively interactive segment to, thereby, induce a modulation in the conductance of the selectively interactive segment. A species may modulate the conductance of a selectively interactive segment in any manner, as described in greater detail below.

As described above, interact refers to any association between a selectively interactive segment of a nanowire and a species that results in a modulation in the conductance of the selectively interactive segment, where modulation in the conductance may include inducing a current in the selectively interactive segment. An association between a selectively interactive segment and a species refers to a physical proximity between the selectively interactive segment and the species. For example, a species may associate with a selectively interactive segment by absorbing, attaching, or binding to the selectively interactive segment. This physical proximity between the selectively interactive segment and the species may be influenced by a property of the species. A property of a species is a characteristic of the species that tends to provide an attraction of the species to another material, such as the material in a selectively interactive segment. The attraction may be the binding, absorbing or attaching to the selectively interactive segment. The strength of the attraction may also be a factor. For example, a strong binding may be needed to cause a change in conductance for a segment. The property of the species facilitates the association of the species to the interactive segment. A property of a species may include a characteristic, such as the number of valance electrons of a species, which allows the species to form ionic bonds, hydrogen bonds, dipole-dipole bonds, Van der Walls force interactions, aromatic bonds, covalent bonds, metallic bonds, etc. Therefore, if a property of a species allows the species to associate with the selectively interactive segment, such as by binding, the species may modulate the conductance of the selectively interactive segment. Conversely, if a species lacks a property that would allow the species to associate with a selectively interactive segment, then that species will not interact with the selectively interactive segment; e.g., will not modulate the conductance of the selectively interactive segment. Furthermore, a species may have multiple properties. For example, a species may have multiple characteristics that allow the species to bind to multiple, different, selectively interactive segments.

According to an embodiment, the nanowires described herein may have a plurality of variant selectively interactive segments. Variant selectively interactive segments means that a plurality of selectively interactive segments of a nanowire are different from each other, yet specifically configured to interact with one or more species. In particular, each variant selectively interactive segment may be configured to detect a different property of the species. The one or more species may be one species or multiple species.

Selectively interactive segments may be made variant using known techniques. For example, variant selectively interactive segments may be created by forming segments of different composition along the length of the nanowire using known processes of forming a nanowire. In other examples, segments are made variant by using different doping in segments or by being differently functionalized or by using a combination of different composition, different doping, and/or being differently functionalized. Functionalizing is attaching molecules or other substances to the surface of the segment; therefore, functionalizing may include coating. Using these processes, two adjacent selectively interactive segments of the nanowire may be made variant because they contain different materials from each other. However, despite their differences, both selectively interactive segments may be specifically designed to interact with the same species or a class of species. In another embodiment multiple nanowires may be connected in parallel and at least two of the nanowires are differentially variant. Differentially variant means that of the at least two nanowires, at least one selectively interactive segment in one of the nanowires is different from at least one selectively interactive segment in the other nanowire. The segments may be made different, for example, by different compositions, different functionalization, or different doping, such as described above.

With regard to doping, doping of the nanowire or one or more of its segments refers to the process of introducing any impurity atoms or particles into a base material. Dopants may be added during growth by introducing a gas containing the desired dopant atoms, or segments may be doped after deposition, most readily from a gaseous source containing the dopant atoms or by diffusion from a doped oxide, or possibly by ion implantation.

Forming and doping nanowires is generally known in the art and described, for example, in U.S. Pat. No. 7,087,920 filed Jan. 21, 2005, to Kamins, which is hereby incorporated herein by reference in its entirety. Processes of creating nanowires are also described in the published articles incorporated by reference below. Any of the methods and the materials for doping, functionalizing, varying composition, and forming nanowires described in these documents may be used to create the variant selectively interactive segments of the nanowires.

With regard to functionalizing, segments of the nanowire may be functionalized by, for example, adding a particular probe DNA/PNA to the nanowire, which binds the complementary DNA and does not significantly bind non-complementary DNA strands. DNA binding has been described by Li et al in “Sequence-specific label-free DNA sensors based on silicon nanowires,” Nano Letters, Vol. 4, pp. 245-247 (2004), which is hereby incorporated by reference herein in its entirety. Functionalizing may also include coating. Coating refers to the process of covering exterior portions of a substance with another substance, such as covering a segment of the nanowire with a material. Any material known in the art may be used to functionalize segments to allow the segments to interact with a particular species, including organic, inorganic, ligands, chemical, and biological materials.

According to an embodiment, the entire length of a nanowire may contain variant selectively interactive segments, each configured to interact with a common species or with multiple species within the same class of species. Therefore, when each variant selectively interactive segment along the entire length of the nanowire simultaneously interacts with the common species or with multiple species within the same class of species, the resulting modulation in conductance of each selectively interactive segment will result in the overall modulation in conductance of the entire nanowire. This overall modulation in conductance may be measured to detect the presence of the species or the class of species interacting with the selectively interactive segments. That is, the species or combination of species is detected only when the conductance of the entire nanowire is modulated, and the modulation in conductance of the entire nanowire only occurs when each of the constituent selectively interactive segments interacts with the species or class of species.

Accordingly, because a single nanowire contains variant selectively interactive segments, each configured to interact with a common species or class of species, the nanowires described herein provide much more accuracy in detecting a species or a class of species. This is because, in order for a species or class of species to be detected, the species or class of species must interact with a plurality of variant selectively interactive segments. In particular, the species interacting with the plurality of variant selectively interactive segments may be indicative of detecting multiple properties of the species. Thus, the use of multiple variant selectively interactive segments provides, in effect, a redundancy along a single nanowire to independently verify that the species or class of species has been detected. Essentially, each variant selectively interactive segment is operable to act as an independent sensor, because each variant selectively interactive segment must interact to modulate the overall conductance of the nanowire and detect the multiple properties of the species. Therefore, the nanowires described herein provide a far greater accuracy in detecting a species or class of species, than is possible with conventional nanowire sensors.

Moreover, the nanowires described herein may interact with multiple species in an analyte to detect the composition of the analyte. The detection of multiple species in the analyte provides a more accurate detection of a substance having the multiple species.

The term nanowire, as used herein, refers to a nanostructure characterized by at least one and preferably at least two physical dimensions that are less than about 500 nanometers (nm), or about 200 nm, or about 150 nm, or about 100 nm, or about 50 nm, or about 25 nm or even less than about 10 nm or 5 nm. Nanowires typically have one principle axis that is longer than the other two principle axes and consequently have an aspect ratio greater than one. The longer axis is referred to as the length. In an embodiment, the nanowire may have an aspect ratio greater than about 10, greater than about 20, or greater than about 100, 200, or 500.

A nanowire in the nanowire sensor may have any length. In certain embodiments, a nanowire may range in length from about 10 nm to about 150 micrometers (μm). In an embodiment, the length of the nanowires 100 and 102 may range from more than about 500 nm to less than about 100 μm, or from about 1 μm to less than about 80 μm.

The nanowire may have any diameter and will typically have diameters ranging from 5 to 200 nm. Although precise uniformity of the diameter of the nanowire is not required, in certain embodiments, the nanowire may have a substantially uniform diameter along its length, such that essentially no substantial tapering or change of the diameter occurs along the length of the nanowire.

The length/diameter ratio of the nanowire may be set to avoid fringing fields. For example, a charge carried by a species may produce an electromagnetic field extending from the species. This species may associate with a selectively interactive segment and the electromagnetic field of the species may interact and modulate the conductance of the selectively interactive segment. The length of the nanowire and subsequently the lengths of the selectively interactive segments of the nanowire may be increased to reduce unwanted interaction between the electromagnetic field of the species and an adjacent selectively interactive segment disposed along the length of the nanowire.

The nanowire may be made from materials known to be used in the composition of nanowires. In certain embodiments, the nanowire may be substantially crystalline and/or substantially non-crystalline. The nanowire may be substantially homogeneous in material, or in certain embodiments heterogeneous. That is, the nanowire may be fabricated from a single material or from a combination of materials. Essentially, any reasonably suitable material or materials may be used to form the nanowire. Examples of suitable materials include semiconductor materials such as, Si, Ge, InP, GaAs, GaN, GaP, InAs, and/or an appropriate combination of two or more such semiconductors, such as InGaAs.

The nanowire may be created by any method known in the art, including, but not limited to, chemical vapor deposition (CVD), metal-organic chemical vapor deposition (MOCVD), and laser ablation techniques. A vapor-liquid-solid (VLS) mechanism may be used to grow the nanowires. For example, nanoparticles may be formed on a substrate. The formation of nanoparticles on substrates is known, and is disclosed, for example, in U.S. patent application Ser. No. 10/281,678, filed Oct. 28, 2002, to Kamins et al. and U.S. patent application Ser. No. 10/690,688, filed Oct. 21, 2003, to Kamins et al., the contents of both of which are incorporated herein by reference in their entirety. Nanowires may also be formed horizontally such that they bridge two terminals, such as two electrodes. Suitable methods of forming bridging nanowires are disclosed, for example, in U.S. patent application Ser. No. 11/022,123 filed Dec. 23, 2004, to Kamins et al.; Islam, M. Saif, “Ultrahigh-density silicon nanobridges formed between two vertical silicon surfaces,” Nanotechnology 15, L5-L8 (Jan. 23, 2004); and Islam, M. Saif, “A novel interconnection technique for manufacturing nanowire devices,” Appl. Phys. A80, 1133-1140, Mar. 11, 2005, all of which are incorporated herein by reference in their entirety.

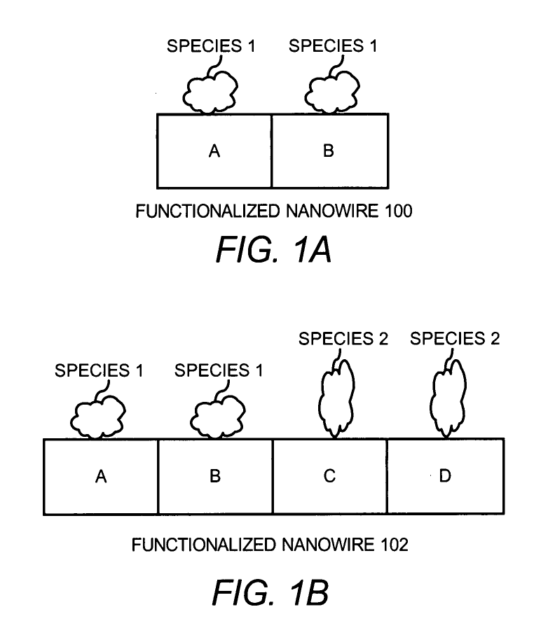

FIGS. 1A and 1B illustrate an example of nanowires 100 and 102, that may be used in a nanowire sensor according to an embodiment. The nanowire 100 has two variant selectively interactive segments, A and B, while the nanowire 102 has four variant selectively interactive segments A, B, C, and D. However, a person having ordinary skill in the art will appreciate that the nanowires 100 and 102 may have any number of variant selectively interactive segments.

As set forth above, the variant selectively interactive segments may be formed, for example, by doping or functionalizing segments differently, and/or by forming segments with different materials. For example, each of the variant selectively interactive segments A-D may be formed with a different material, coated with a different material or doped differently from the other segments.

The variant selectively interactive segments may be disposed along the longitudinal axis of the nanowires 100 and 102, as depicted in FIGS. 1A and 1B, and may occupy any length or area of the nanowire 100 or 102. While FIGS. 1A and 1B depict the variant selectively interactive segments as substantially equal in length along the longitudinal axis of the nanowires 100 and 102, different lengths may be used. For example, variant selectively interactive segment A may be two or three times as long as the variant selectively interactive segment B.

As FIGS. 1A and 1B depict, the variant selectively interactive segments may be aligned in series along the longitudinal axis of the nanowires 100 and 102. In series means that the selectively interactive segments have the ability to allow current to flow from one longitudinal end of the nanowires 100 and 102 to the other longitudinal end of the nanowires 100 and 102 along a single path. If the nanowire 100 or 102 is formed between two electrodes, as will be described in greater detail below, the nanowire 100 or 102 may carry current from one electrode to the other; the current can be measured to determine whether the nanowire 100 or 102 is in a conducting state or a non-conducting state.

The nanowires 100 and 102 may be customized to detect a specific species or class of species or different species not in the same class by providing particular variant selectively interactive segments in the nanowires 100 and 102. In particular, the selectively interactive segments may be made variant so the nanowires 100 and 102 may be used to detect different properties of a species or different properties of multiple species. For example, the nanowire 100 is configured to detect multiple properties of a single species 1. Variant selectively interactive segment A is composed of a material that causes species 1 to bind to segment A. The ability to bind with this material is one property of species 1. Variant selectively interactive segment B is coated, for example, with material that causes species 1 to bind to segment B, and segment A is not coated with this material. The coating on B of the nanowire 100 may be formed from different materials. The ability to bind to this coating is another property of species 1. FIG. 1A shows species 1 binding with variant selectively interactive segments A and B. If species 1 simultaneously binds with variant selectively interactive segments A and B, a current may be induced in both variant selectively interactive segments A and B. Thus, the nanowire 100 may be changed from a non-conducting state to a conducting state, which is indicative of the multiple properties of species 1 being detected. While a coating is used to describe the selectively interactive segments in this example, a person having ordinary skill in the art will appreciate that any other method of creating a selectively interactive segment may be used in place of, or in conjunction with, a coating.

A nanowire may be customized to detect multiple species. For example, as shown in FIG. 1B for the nanowire 102, variant selectively interactive segments A and B are configured to detect different properties of species 1, and variant selectively interactive segments C and D are configured to detect different properties of species 2. If species 1 interacts with variant selectively interactive segments A and B, and species 2 interacts with variant selectively interactive segments C and D, all at the same time as shown in FIG. 1 B, the nanowire 100 may change from a non-conducting state to a conducting state, which is indicative of the multiple properties of species 1 being detected and multiple properties of species 2 being detected.

The multiple species may be in the same class. For example, species 1 and species 2 are overlapping in that they contain a common molecule. If variant selectively interactive segments A-D detect species 1 and 2, the molecule may be detected. In another example, the species 1 and 2 are different species known to be in a substance. For example, an analyte, such as a popular soft drink, may be known to contain species 1 and species 2. A conventional nanowire can only detect one of the species in the soft drink. Detection of the one species could provide an indication that the analyte might be the soft drink. However, this determination is prone to a high rate of error because many other substances, including other types of soft drinks, may also possess the one detected species. Therefore, the detection of only the one species may provide a false positive indication of the identity of the soft drink, because there is no way of determining that the one detected species actually came from the popular soft drink and not from another analyte. In contrast to conventional nanowires, the nanowire 102 having a plurality of variant selectively interactive segments may simultaneously detect both species one and two, thus providing a more accurate determination that the analyte is the popular soft drink.

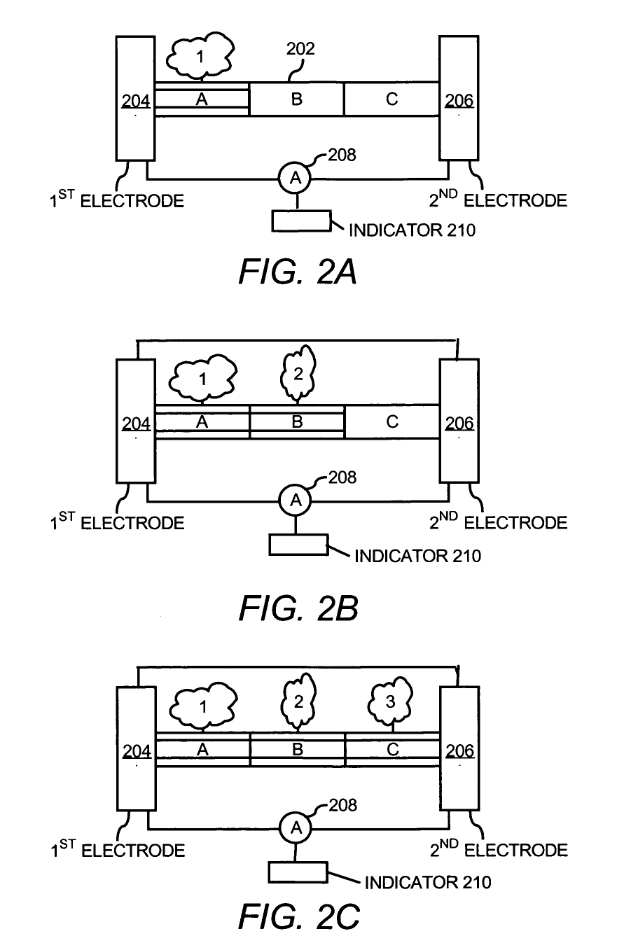

FIGS. 2A-C illustrate an example of a nanowire sensor 200 interacting with species 1-3, according to an embodiment. The nanowire sensor 200 includes a nanowire 202 having three variant selectively interactive segments A, B, and C, each configured to interact with species 1, 2, and 3, respectively.

The nanowire 202 bridges a first electrode 204 and a second electrode 206. The nanowire sensor 200 includes a measuring device 208. The measuring device 208 may be software, hardware, or any combination of software and hardware operable to electrically stimulate the nanowire, measure current and used to determine whether the nanowire 202 is in a conducting state or non-conducting state depending on the amount of measured current. Therefore, the measuring device 208 may include a device, which causes current to flow through the nanowire 202, such as a voltage source.

In FIG. 2A, the nanowire sensor 200 is exposed to an analyte containing species 1, but not species 2 or 3. The selectively interactive segment A is configured to interact with species 1. Thus, a property, such as a binding property, of species 1 may facilitate an association, such as an ionic bond, between species 1 and the selectively interactive segment A.

Species 1 carries a charge. Therefore, when species 1 binds to segment A, the charge of species 1 modulates the conductance of segment A. For instance, the interaction may result in a high conductance induced in segment A.

As FIG. 2A depicts, a high conductance is induced in segment A as a result of the interaction between segment A and species 1. However, segments B and C in FIG. 2A have not interacted. Therefore, segments B and C have a high resistance and current cannot flow through the entire nanowire 202. The conductance of the entire nanowire 202 has not been substantially altered, so the measuring device 208 will not detect an appreciable modulation in current and therefore a modulation of the conductance of the nanowire 202. In effect, the nanowire 202 remains in the “off” or non-conducting state.

In FIG. 2B, the nanowire sensor 200 is exposed to an analyte containing species 1 and 2, but not species 3. Therefore, the selectively interactive segments A and B interact with species 1 and 2, respectively. The interaction results in a modulation in the conductance of the selectively interactive segments A and B. However, because the conductance of segment C remains substantially unchanged, the measuring device 208 does not detect an appreciable modulation in conductance of the entire nanowire 202. The nanowire 202 is still in the non-conducting state.

However, in FIG. 2C, the nanowire sensor 200 is exposed to an analyte containing species 1, 2, and 3. Therefore, the selectively interactive segments A, B, and C simultaneously interact with species 1, 2, and 3, respectively. The interaction includes a modulation in the conductance of segments A, B, and C. Therefore, the conductance of the entire nanowire 202 has changed, which may be detected by the device 208. For example, species 1, 2, and 3 may induce current flow in the entire nanowire 202. Thus, the measuring device 208 may detect that the nanowire 202 is now in the conducting state.

The detection of the modulation in conductance of the nanowire 202 to, for example, a conducting state from a non-conducting state, results in the detection and identification of the analyte, because the analyte contains species 1, 2, and 3 and the variant selectively interactive segments A, B and C were configured to interact with species 1, 2, and 3, respectively. Thus, the nanowire sensor 200 may perform an operation equivalent of an AND logic function. When a modulation in conductance of the nanowire 202 is detected, the nanowire sensor 200 has determined that 1 AND 2 AND 3 have interacted with the nanowire 202 and, thus, are present in the analyte. That is, when the nanowire 202 is not conducting, in this example, then not all of the target species are present. When all of the species 1, 2, and 3 interact with the nanowire 202, the nanowire 202 is, in effect, “turned on” by species 1, 2, and 3 and is in a conducting state.

The nanowire sensor 200 may also include an indicator 210. The indicator 210 may be any software, hardware, or combination of software and hardware, which is operable to convey a detection of a modulation in conductance to a user. The indicator 210 may be visual, such as a message on a computer screen. The indicator 210 may also be auditory, such as an alarm sound. Therefore, when a modulation in conductance is detected, the nanowire sensor 200 may alert a user that the species for which the nanowire 202 was designed to interact with has been detected.

The embodiment of FIGS. 2A-C describes the nanowire 202 as being in essentially two states, conducting or non-conducting. That is, a current is either flowing through the nanowire 202 or it is not. However, a person having ordinary skill in the art will appreciate that the nanowire 202 may have different levels of conductance, which may be measured by the measuring device 208. For example, the nanowire 202 may have a relatively low level of current flowing through the nanowire 202. This current may be measured. When the nanowire 202 interacts with species 1, the current may increase a moderate amount and this moderate increase in conductance may be measured. Similarly, when the nanowire 202 interacts with species 2, the current further increases, and, of course, further increases when the nanowire 202 interacts with species 3.

While, the measuring device 208 may measure this gradual increase in conductance, the device 208 may determine that species 1, 2, and 3 are present only when the conductance changes above a certain threshold value. When this threshold value is reached, the device 208 may determine that the analyte containing species 1, 2, and 3 is present.

In addition, the embodiments described above have been described to include a variant selectively interactive segment changing from non-conducting to conducting in response to the segment interacting with a particular species. Then, when all the variant selectively interactive segments in a nanowire change from a non-conducting to a conducting state, the properties the segments were configured to detect are detected and the entire nanowire changes from a non-conducting to a conducting state. In another embodiment, the nanowire is normally in a conducting state (when not interacting). However, when a variant selectively interactive segment in the nanowire is exposed to a species that it is designed to interact with, the segment becomes non-conducting. Thus, the nanowire becomes non-conducting, which is indicative that one of the properties of a species that the nanowire was designed to detect is being detected. In effect, the nanowire performs an OR logic function, because if the nanowire changes to a non-conducting state, at least one of the properties the nanowire was configured to detect has been detected.

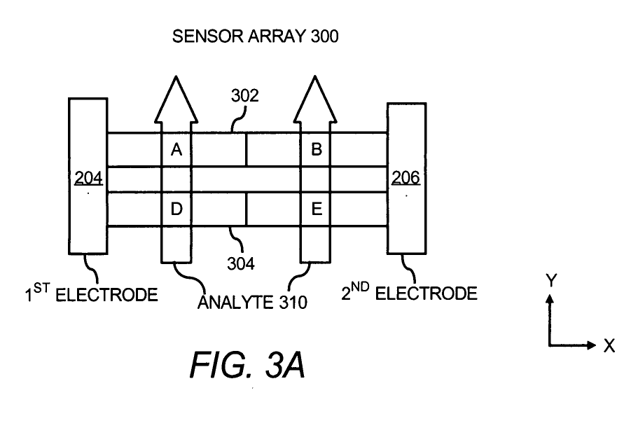

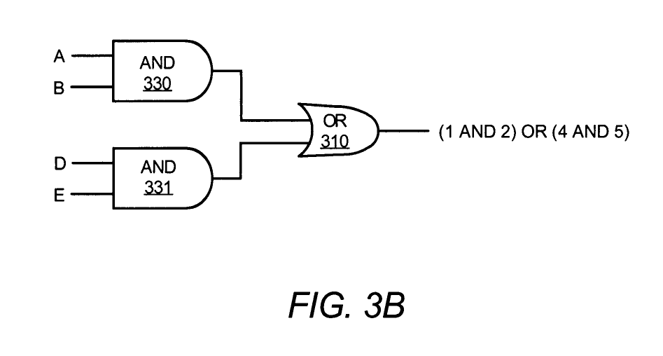

FIG. 3A illustrates a nanowire sensor array 300, according to an embodiment including a plurality of nanowires 302 and 304 connected in parallel. The nanowire 302 has variant selectively interactive segments A and B, and the nanowire 304 has variant selectively interactive segments D and E. While the nanowires 302 and 304 are each depicted with two selectively interactive segments, respectively, a person having ordinary skill in the art will appreciate that the nanowires 302 and 304 may have any number of selectively interactive segments arranged in any configuration. Moreover, the nanowire sensor array 300 may include only one nanowire having variant selectively interactive segments. Similarly, the sensor array 300 may include more nanowires and other components not illustrated in FIG. 3A, such as the measuring device 208 and the indicator 210 described above, with respect to FIGS. 2A-C.

The nanowires 302 and 304 bridge a first and second electrode 204 and 206, which may be similar to the first and second electrodes 204 and 206 described in FIG. 2. The nanowires 302 and 304 are connected in parallel between the first and second electrodes 204 and 206. That is, the nanowires 302 and 304 each provide a current path in a parallel circuit.

In FIG. 3A, the variant selectively interactive segments A, B, D, and E are configured to interact with species 1, 2, 4, and 5, respectively. In this manner, the selectively interactive segments of the sensor array 300 are variant in the “Y” coordinate direction, as well as the “X” coordinate direction. That is, each nanowire 302 and 304 is variant along the longitudinal “X”-axis of the nanowire due to the variant selectively interactive segments A and B aligned in series and the variant selectively interactive segments D and E aligned in series, respectively. Because the nanowires 302 and 304 are arranged in a substantially parallel orientation with the longitudinal axis of each nanowire 302 and 304 in the “X” coordinate direction, the sensor array 300 is also variant in the “Y” coordinate direction and, therefore, different species may be detected along the Y axis of the sensor array 300. Also, FIG. 3A is an example of using multiple nanowires. In another example, one of the nanowires may not have multiple variant selectively interactive segments and could be configured to detect one property of a species.

For example, an analyte 310 may be exposed to the sensor array 300, such that the analyte 310 flows between the first and second electrodes 204 and 206 to contact both the nanowire 302 and the nanowire 304, as indicated by the two arrows shown in FIG. 3A. The sensor array 300 may detect four different species because the sensor array 300 contains four different selectively interactive segments, each of which is capable of interacting with a different species.

Logic may be built into the sensor array 300, such that the sensor array 300 performs an operation equivalent to a logic gate as a result of an exposure of the sensor array 300 to an analyte. The operation may result in an indication that certain species may be present in the analyte. For example, the sensor array 300 may be exposed to an analyte containing some or all of species 1, 2, 4 and 5. These species may interact with the variant selectively interactive segments A, B, D, or E and may change the nanowires 302 or 304 from a non-conducting state to a conducting state.

FIG. 3B shows the logic functions performed by the sensor array 300. For example, each of the nanowires 302 and 304 in the sensor array 300 perform an AND function, as illustrated by AND gates 330 and 331, respectively. For example, if selectively interactive segments A and B interact with species 1 and 2, respectively, species 1 and 2 have been detected and the nanowire 302 is in a conducting state. If selectively interactive segments C and D interact with species 4 and 5, respectively, species 4 and 5 have been detected and the nanowire 304 is in a conducting state. Because nanowires 302 and 304 are connected in parallel, which is represented by the OR gate 310 in FIG. 3B, if either nanowires 302 and 304 are conducting, species (1 and 2) or species (4 and 5) are detected.

Conversely, in other embodiments, the nanowires 302 and 304 may be “turned off” as a result of an interaction between a species and a selectively interactive segment. That is, current may be induced to flow through the nanowires 302 and 304 before the nanowire sensor array 300 is exposed to an analyte. However, the variant selectively interactive segments may be configured on the nanowires 302 and 304 such that the interaction of a species and a segment substantially reduces the current flowing through the nanowire. In this embodiment, each of the nanowires 302 and 304 function as an OR gate and the connection in parallel performs the function of an AND gate.

A smaller amount of higher quality information is obtained from the sensor array 300, as compared to the combination of conventional nanowire sensors needed to accomplish the same detection. The number of electronic signals that need to be transported and the amount of required computation external to the sensor is reduced by performing some of the computation within the sensor itself. For example, if the conductance of either nanowire 302 or 304 is above a threshold, then the sensor array 300 may indicate simply that either species 1 and 2 or species 3 and 4 caused the signal, and, thus, that either species 1 and 2 or species 3 and 4 are present in the analyte. Further calculations performed external to the sensor array are not required to obtain an accurate result. Also, the area needed for interconnecting the nanowires is substantially reduced by using a parallel set of nanowires between only one pair of electrodes 204 and 206, instead of multiple pairs of electrodes.

Moreover, the sensor array 300 is extremely sensitive allowing for the detection of a small quantity of a species in a fluid, because the nanowires 302 and 304 provide a large surface area where the fluid may interact with the nanowires 302 and 304. Detection often relies on sensing a property such as a change in conductance, so the volume of the nanowires 302 and 304 may be reduced as much as feasible to increase the surface to volume ratio; e.g., the fraction of the volume that is affected by surface charges.

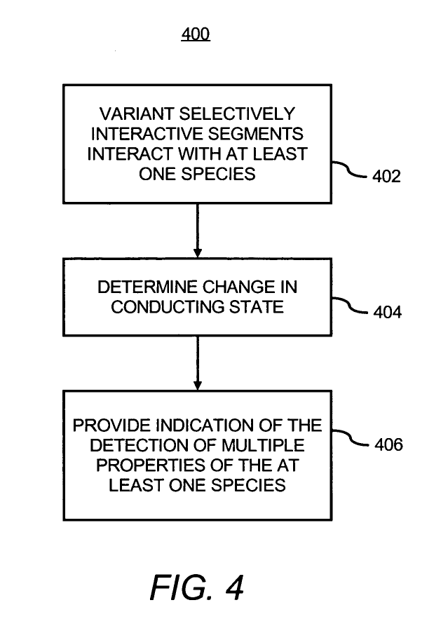

FIG. 4 illustrates a flow chart of a method 400 for detecting at least one species with a nanowire sensor. The method 400 is described with respect to the nanowire sensors shown in FIGS. 1-3 by way of example and not limitation. A person having ordinary skill in the art will appreciate that additional steps may be added to the method 400 and, similarly, not all the steps illustrated in FIG. 4 may be necessary to identify an analyte with a nanowire sensor. The method 400 may utilize at least one nanowire having a plurality of variant selectively interactive segments and each of the plurality of variant selectively interactive segments is configured to interact with at least one species. The nanowire may be similar to the nanowire 202 described with respect to FIGS. 2A-C or the nanowires 302 or 304, described with respect to FIG. 3A. The nanowire used to practice the method 400 may be exposed to an analyte.

At step 402, the plurality of variant selectively interactive segments of the nanowire interact with at least one species. The interaction may include a species associating with the plurality of variant selectively interactive segments and a charge on the species modulating the conductance of each of the plurality of variant selectively interactive segments.

At step 404, a change in a conducting state of at least one nanowire is determined. For example, prior to step 402, the nanowire may be in a low conductance state. That is, the nanowire may have a high resistance. The change in this state may be a reduction in the resistance or an increase in the conductance. The change in the conducting state may be determined by the measuring device 208.

At step 406, an indication of the detection of the multiple properties of the at least one species is provided. The indication may be, for example, a message on a computer screen or an auditory alarm, which notifies a user of the change in the conducting state.

While the embodiments have been described with reference to examples, those skilled in the art will be able to make various modifications to the described embodiments. The terms and descriptions used herein are set forth by way of illustration only and are not meant as limitations. In particular, although the methods have been described by examples, steps of the methods may be performed in different orders than illustrated or simultaneously. Those skilled in the art will recognize that these and other variations are possible within the spirit and scope as defined in the following claims and their equivalents.

1. A nanowire sensor operable to detect at least one species, the nanowire sensor comprising:
at least one nanowire having a plurality of variant selectively interactive segments, wherein each of the variant selectively interactive segments is configured to simultaneously interact with the at least one species to modulate the conductance of the nanowire for detecting the at least one species.

2. The nanowire sensor of claim 1, wherein the at least one nanowire changes conducting state if the at least one species interacts with all the variant selectively interactive segments simultaneously.

3. The nanowire sensor of claim 2, wherein the at least one species interacting with all the variant selectively interactive segments simultaneously comprises the at least one species associating with all the variant selectively interactive segments to induce a conducting state in all the variant selectively interactive segments to change the nanowire from a non-conducting state to a conducting state.

4. The nanowire sensor of claim 2, further comprising:
a measuring device, wherein the measuring device is operable to detect a change in conducting state to identify the at least one species.

5. The nanowire sensor of claim 2, further comprising:
an indicator connected to the measuring device and operable to indicate that the at least one species is detected.

6. The nanowire sensor of claim 1, wherein each of the plurality of variant selectively interactive segments is configured to detect a different property of the at least one species, such that when all the variant selectively interactive segments simultaneously interact with the at least one species, all the different properties are detected.

7. The nanowire sensor of claim 1, further comprising:
electrodes, wherein the at least one nanowire bridges the two electrodes.

8. The nanowire sensor of claim 1, wherein the at least one nanowire is configured to perform an operation equivalent to an AND logic function as a result of all the variant selectively interactive segments simultaneously interacting with the at least one species for detecting the at least one species.

9. The nanowire sensor of claim 1, wherein the plurality of variant selectively interactive segments are in a conducting state when not interacting with the at least one species and in a non-conducting state when interacting with the at least one species and the at least one nanowire is configured to change its conducting state if at least one of the variant selectively interactive segments interacts with the at least one species.

10. The nanowire sensor of claim 9, wherein the at least one nanowire is configured to perform an operation equivalent to an OR logic function if at least one of the variant selectively interactive segments interacts with the at least one species.

11. The nanowire sensor of claim 1, wherein the plurality of variant selectively interactive segments are arranged in series along the length of the at least one nanowire.

12. The nanowire sensor of claim 1, wherein the plurality of variant selectively interactive segments are comprised of (1) different compositions, (2) differently doped segments, (3) differently functionalized segments, or are comprised of a combination of (1)-(3).

13. The nanowire sensor of claim 1, wherein the at least one nanowire sensor comprises a plurality of nanowires and two electrodes, wherein the plurality of nanowires are connected in parallel between the two electrodes and the plurality of nanowires include a first nanowire and a second nanowire, wherein at least one selectively interactive segment of the first nanowire is differentially variant from at least one selectively interactive segment of the second nanowire.

14. The nanowire of claim 13, wherein the at least one species is operable to be detected if all the selectively interactive segments from a first nanowire of the plurality of nanowires simultaneously interact with the at least one species, or if all the selectively interactive segments from a second nanowire of the plurality of nanowires simultaneously interact with the at least one species.

15. The nanowire sensor of claim 13, wherein the plurality of nanowires are configured to perform an operation equivalent to an OR logic function such that all the selectively interactive segments from a first nanowire of the plurality of nanowires simultaneously interacting with the at least one species, or all the selectively interactive segments from a second nanowire of the plurality of nanowires simultaneously interacting with the at least one species is operable to be used to detect the at least one species.

16. The nanowire sensor of claim 15, wherein the first and second nanowires change from a non-conducting state to a conducting state only if all the selectively interactive segments in the first or second nanowire interact with the at least one species.

17. The nanowire sensor of claim 13, wherein the plurality of nanowires are configured to perform an operation equivalent to an AND logic function such that if a first nanowire of the plurality of nanowires changes from a conducting state to a non-conducting state and a second nanowire of the plurality of nanowires changes from a conducting state to a non-conducting state, then detection of both non-conducting states indicates detection of the at least one species.

18. The nanowire sensor of claim 17, wherein a variant selectively interactive segment in each of the first and second nanowires interacts with the at least one species to cause the variant selectively interactive segment in each of the first and second nanowires to become non-conducting.

19. The nanowire sensor of claim 1, wherein the at least one species comprises one of a single species, multiple species in one class, and multiple species in different classes.

20. A nanowire configured to interact with at least one species, the nanowire comprising:
a plurality of variant selectively interactive segments, wherein each of the variant selectively interactive segments are configured to simultaneously interact with the at least one species to modulate the conductance of the nanowire.

21. The nanowire of claim 20, wherein the at least one nanowire is customized to interact with a particular species or multiple species for detecting a plurality of properties of the particular species or the multiple of species.

22. The nanowire of claim 20, wherein the at least one species interacting with all the variant selectively interactive segments simultaneously comprises the at least one species associating with all the variant selectively interactive segments to induce a current in all the variant selectively interactive segments to change the nanowire from a non-conducting state to a conducting state.

23. A method of detecting at least one species with a nanowire sensor, the nanowire sensor having at least one nanowire with a plurality of variant selectively interactive segments, the method comprising:
the plurality of variant selectively interactive segments interacting with the at least one species, wherein each variant selectively interactive segment is configured to detect a property of the at least one species; and
determining a change in conducting state of the at least one nanowire for detecting multiple properties of the at least one species.

24. The method of claim 23, further comprising:
providing an indication of the detection of the multiple properties of the at least one species.
